(19) United States
(12) Patent Application Publication
(10) Pub. No.: US 2007/0220745 A1
(43) Pub. Date: Sep. 27, 2007

(54) Method for Producing Traverse Connections in Printed Circuit Board Sets

(75) Inventor: Georg Busch, Ahaus (DE)

Correspondence Address: BELL, BOYD & LLOYD, LLP, P.O. BOX 1135, CHICAGO, IL, 60690, US

(73) Assignee: Siemens Aktiengesellschaft, Muenchen (DE)

(21) Appl. No.: 11/568,495

(22) PCT Filed: Mar. 2, 2005
(86) PCT No.: PCT/EP05/50918

§ 371 Date: Oct. 30, 2006

(30) Foreign Application Priority Data
Apr. 29, 2004 (DE) 10 2004 021 063.2

(51) Int. Cl. H05K 3/00; H01K 3/10

(52) U.S. Cl. 29/852; 29/846; 29/831

(57) ABSTRACT

A method for producing printed circuit board sets capable of being made, among other things, without adhesive, in flexible manner and with very small transverse connections with diameters of the order of 1 to 3 μm. The method uses, as starting material for the printed circuit board set, a support element free of any copper layer. The through holes, in particular for the smallest transverse connection, are made by spraying heavy ions into the obtained material. Only subsequently the surface of the support element are coated with a copper film. The electrical transverse connections are thus simultaneously produced. If the support element is, for example, flexible polyimide and it has not been pretreated for the copper plating, it is possible to use the heavy ion process not only to produce the holes, but also to make the surface rough. The desired printed circuit board set is then completed according to the usual methods.

### FIELD OF TECHNOLOGY

The invention relates to a method for producing transverse connections for printed circuit boards.

### BACKGROUND

In methods for producing two-layered or multi-layered printed circuit board sets, transverse connections in general and especially micro-transverse connections on a minimum of space with a pad diameter less than 200 μm pose a problem. Using current technology, micro-vias can for example be manufactured with a hole diameter of 75 to 100 μm and a pad diameter of 250 to 300 μm.

Corresponding details emerge from the documentation of, for example, the company P.C.M. GmbH, Hattsteiner Allee 17, 61250 Usingen, URL: http://www.p-m-c.de/Produkte/Standardleiterplatten/tech-rdllp_d.htm.

Additionally the document WO 2004/015161 discloses a method and an arrangement for processing support material using heavy ion irradiation and a subsequent etching process, which are used to roughen the surface of a support element of a printed circuit board set or of the support material of the printed circuit board set, so that a copper layer to be subsequently applied to the correspondingly processed surface of the support element or of the support material adheres securely there.

Roughening the surface is especially important if the copper layer is applied to the support element or support material without adhesive and if the support element or support material is plastic, for example polyimide.

Polyimide (PI) is used for high-quality printed circuit board sets which can be bent, in other words are flexible. Other examples of such support elements are polyethylene naphthalate (PEN) or polyester (PET). For rigid circuit board sets CEM1, FR2 or FR4 can for example be used as the support element.

In existing production processes for the production of printed circuit board sets, support elements which are already coated with copper are used at the time the transverse connections are realized. The result of this is that when producing the electrical transverse connections another copper layer is applied at least in some places, as a result of which the thickness of the printed circuit board set finally obtained is increased. Additionally the effort involved in applying the first copper layer has been virtually redundant. A further disadvantage is that the thicker copper layer obtained overall only permits a cruder circuit board conductor structure than a thinner overall copper layer. Moreover, efforts should be made to achieve a further reduction of the space requirement for the transverse connections, so that for example more can be accommodated on a predefined surface of the printed circuit board set than previously.

U.S. Pat. No. 6,153,060, which is incorporated by reference in its entirety herein, discloses a method in which transverse connections are produced by laser drilling in a substrate, such as polyimide for example. When these transverse connections are produced, a carbonaceous ring (or “laser slag”) is created, which is then removed by means of an ion etching process.

### BRIEF SUMMARY

An exemplary method is disclosed for producing printed circuit board sets of the type referred to in the introduction, where the method has a simplified production process which enables the production of very small transverse connections, and which can also be used for printed circuit board sets which are produced without adhesive and are flexible.

### BRIEF DESCRIPTION OF THE DRAWING

The various objects, advantages and novel features of the present disclosure will be more readily apprehended from the following Detailed Description when read in conjunction with the enclosed drawings, in which:

FIG. 1 discloses an exemplary embodiment disclosing a method for producing transverse connections.

### DETAILED DESCRIPTION

Preferably, support elements are used at the time of production of the transverse connections, said support elements not as yet having a copper layer on the surfaces. Thus up to this point those production steps are dispensed with which are necessary for applying these layers to the support element. Thus the overall procedure for producing the printed circuit board set is ultimately simplified.

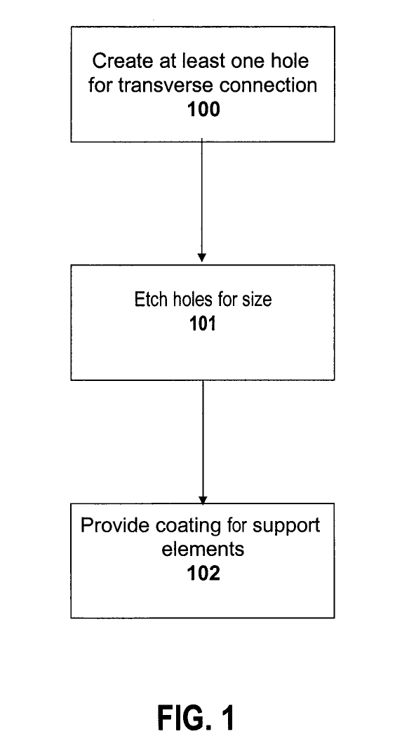

Turning to FIG. 1, before applying any layers, at least one single hole is created 100 in each case at points on the subsequent printed board set which are provided for transverse contacts, using a hole production method for producing at least one single hole in each case at a relevant point in each case.

The hole production method can for example be the method of drilling, applying a laser beam or bombardment with heavy ions. The latter has the particular advantage that very small transverse connections can be achieved.

With the aid of a subsequent etching process the fabricated holes can be etched to a desired size 101. If the hole production method used entails creating more than one single hole next to each other at one point simultaneously, as is possible for example in the case of a bombardment using heavy ions, holes lying close to one another can be merged together to form a single hole of the desired size. Such a final hole then for example has a hole diameter of 1 to 3 μm, which at present represents the smallest possible hole for a transverse connection.

The copper coating is not applied to the surfaces of the support element or of the support material of the printed circuit board set until the subsequent method step. Here the electrical transverse connection between the copper coatings is effected 102 at the same time through the holes created in the previous method step.

Since no copper layers were present until now, the thicknesses of the copper coatings are minimal. Thus very fine circuit board conductor structures can be produced using these copper coatings.

Additionally the small diameters of the transverse connections have the advantage that said transverse connections are completely filled with copper when the electrical transverse connections are produced. This is advantageous for a possible maximum current density which can flow via these transverse connections, and is advantageous as regards an even surface of the support element. Hence the transverse connections do not need to be additionally filled in a further method step in order to obtain an even surface.

Finally other method steps can be implemented, in order to achieve precisely the desired printed circuit board set.

Because the transverse connections are very small, multiple transverse connections can correspondingly be envisaged on a given area of the support element or of the printed circuit board set. This is particularly advantageous if for example the printed circuit board set is used for displays in which it is necessary to be able to control a constantly increasing multiplicity of control points.

Heavy ion bombardment can also be used as the hole production method, as already mentioned above. This allows, as already stated, very small transverse connections to be achieved. If no such small transverse connections are required, the holes can also be created using a laser method. If the transverse connections can be even coarser, the holes can also be made using a conventional drilling method.

Also advantageous is the possibility of using flexible materials such as polyimide as a support element, because flexible circuit board sets can be produced therewith. This is the case even with very small transverse connections and very fine circuit board conductor structures.

The process of roughening the surface of the support element to ensure adhesive strength regarding the copper coatings does not need to be carried out in advance if the heavy ion bombardment method is chosen for forming the holes for the transverse connections. The bombardment method can be used simultaneously to roughen the surfaces of the support element in addition to producing the holes for the transverse connections by correspondingly controlling the heavy ion irradiation. At points at which only a roughening of the surface of the support element is desired, the heavy ion irradiation is used correspondingly less intensively. At points at which through holes are desired, the bombardment is correspondingly more intense, so that the heavy ions penetrate the entire thickness of the support element at these points. Costs and manufacturing times are thereby saved.

Associated with the possibility of roughening the surfaces of the support element is the advantage that the printed circuit board set can be realized without adhesive.

While the invention has been described with reference to one or more exemplary embodiments, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiments disclosed as the best mode contemplated for carrying out this invention, but that the invention will include all embodiments falling within the scope of the appended claims.

1-5. (canceled)

6. A method for producing transverse connections in printed circuit board sets comprising a support element, comprising the steps of:
producing at least one hole only in the support element prior to producing further transverse connection elements on at least one of the circuit board sets;
performing an etching process on the at least one hole to expand the at least one hole to a predetermined size;
performing a copper coating process on at least one of a top and bottom side of the support element where further transverse connection elements will be joined; and
fabricating the further transverse connection elements through the holes during the copper coating process.

7. The method according to claim 6, wherein the at least one hole is produced using heavy ion bombardment.

8. The method according to claim 7, wherein, during the heavy ion bombardment, the side of the support element facing the bombardment is positioned to be roughed up during the bombardment process.

9. The method according to claim 6, wherein the support element is made of a polyimide membrane.

10. The method according to claim 6, wherein the printed circuit board set is an adhesive-free printed circuit board set.
